(19) United States
(12) Patent Application Publication
(10) Pub. No.: US 2003/0030127 A1
(43) Pub. Date: Feb. 13, 2003

(54) Bipolar transistor and method of manufacturing same

(76) Inventors: Hendrik Gezienus Albert Huizing, Eindhoven (NL); Jan Willem Slotboom, Eindhoven (NL); Igor Lyuboshenko, Paris (FR); Johan Hendrik Klootwijk, Eindhoven (NL); Freerk Van Rijs, Nijmegen (NL); Joost Melai, Leuven (BE)

Correspondence Address: U.S. Philips Corporation, 580 White Plains Road, Tarrytown, NY, 10591, US

(21) Appl. No.: 10/211,897

(22) Filed: Aug. 2, 2002

(30) Foreign Application Priority Data
Aug. 7, 2001 (EP) 01202997.1

(51) Int. Cl. H01L 27/082; H01L 27/102; H01L 29/70; H01L 31/11

(52) U.S. Cl. 257/565

(57) ABSTRACT

The bipolar transistor comprises a collector region (1) of a semiconductor material with a first doping type, an emitter region (2) with a first doping type, and a base region (3) of a semiconductor material with a second doping type, opposite to the first doping type, which base region is arranged between the emitter region (2) and the collector region (1), and a semiconductor area (4) extending between the collector region (1) and the base region (3).

The collector region (1) is doped such that the semiconductor area (4) is fully depleted and the magnitude of the intrinsic electric field in the semiconductor area (4) is at least substantially independent of the applied doping types and the doping concentration in the semiconductor area (4).

The method of manufacturing the bipolar transistor comprises the step of epitaxially growing a semiconductor layer (6) over a collector region (1) and doping the epitaxial layer (6) in situ, after which the base region (3) is deposited epitaxially.

The comparatively thin semiconductor area (4) between the base region (3) and the collector region (1) allows ultrafast bipolar transistors with a high cutoff frequency and an improved breakdown voltage to be manufactured. The product of the cutoff frequency and the collector-emitter breakdown voltage of these bipolar transistors exceeds the Johnson limit.

The invention relates to a bipolar transistor comprising

a collector region of a semiconductor material with a first doping type,

an emitter region of a semiconductor material with the first doping type, and

a base region of a semiconductor material with a second doping type,

opposite to the first doping type, which base region is situated between the emitter region and the collector region, a semiconductor area extending between the collector region and the base region.

The invention also relates to a method of manufacturing a bipolar transistor comprising a collector region of a semiconductor material with a first doping type onto which a base region of a semiconductor material with a second doping type, opposite to the first doping type, is provided.

JP-A 5-74800 discloses a bipolar transistor comprising SiGe as the semiconductor material in the base region.

Bipolar transistors are used in a large number of applications, inter alia high-frequency RF applications, such as low-noise amplifiers, multiplexers and demultiplexers. Bipolar transistors with a cutoff frequency of typically 100 GHz can suitably be used as a component in optical communications networks for transferring typically 40 Gb/s.

The design of such bipolar transistors is a trade-off between a large number of parameters. An important parameter is the breakdown voltage between the collector and the base or the emitter. In general, the speed of the transistor decreases as the breakdown voltage increases. The speed of the transistor is expressed in a different, important parameter, namely the cutoff frequency. The cutoff frequency is defined as the frequency at which the transistor ceases amplifying the current and the current gain has become equal to 1.

The known heterojunction bipolar transistor comprises SiGe in the base region. The extremely thin SiGe base region is surrounded, on the side of the collector, by an area of semiconductor material. Said area of semiconductor material is an intrinsic or lightly doped material with a doping level of maximally 5×10¹⁶ cm⁻³. As the semiconductor area and the collector region are both n-type doped, this area forms as it were an extension of the collector region. Adjacent to this area, the collector region comprises a part that is comparatively lightly n-type doped with typically 1×10¹⁷ cm⁻³ and a part that is comparatively heavily n-type doped with 1×10²⁰ cm⁻³.

The stepwise build-up of the doping in the collector region leads to a stepwise increase of the electric field in the collector. As a result of this gradient in the electric field, the breakdown voltage is comparatively high.

The semiconductor material of the area on the side of the collector is SiGe or Si. If said semiconductor material is SiGe, then the cutoff frequency is reduced at high current densities as a result of high injection (Kirk effect). If said semiconductor material is Si, i.e. when the doping level of the area is increased to a concentration of maximally 5×10¹⁶ cm⁻³, the cutoff frequency does not decrease at high current densities because the doping of the collector is sufficiently high to ensure that the Kirk effect does not occur anymore. The emitter-collector breakdown voltage is negatively influenced by the increase of the doping in the area.

However, it is known in the field that, in general, the product of the cutoff frequency and the breakdown voltage between the collector and the emitter has a maximum that is commonly referred to as the Johnson limit. This product consequently is an important parameter for bipolar transistors. As the product has a maximum, increasing one of these parameters without reducing the other is generally not possible.

It is an object of the invention to provide a bipolar transistor of the type described in the opening paragraph, which approaches the Johnson limit over a wide frequency range.

In the device in accordance with the invention, this object is achieved in that the collector region is doped such that the semiconductor area is fully depleted and the size of the intrinsic electric field in the semiconductor area is at least substantially independent of the doping types used and the concentration of the doping in the semiconductor area.

The semiconductor area typically has a lower doping concentration than the collector, base or emitter regions, so that the area is depleted of charge carriers. Consequently, the semiconductor area is a depletion region.

Unlike the known bipolar transistor, the collector region comprises only one part of heavily doped semiconductor material. The comparatively high doping of the collector region causes the intrinsic electric field in the fully depleted semiconductor area to be very high, typically >10⁵ V/cm for Si. For other semiconductor materials, such as GaAs, InP, comparable values of the electric field apply, while for SiC and GaN the value of the electric field is approximately a factor of 10 higher. Even if no reverse voltage is applied across the collector base, the built-in voltage is sufficiently high to generate this very high intrinsic electric field. An additional electric field caused by doping atoms in the semiconductor area has hardly any influence on the total electric field, which remains substantially equal to the intrinsic field. The semiconductor area may thus be n-type as well as p-type with a random doping level, the level of the doping being smaller than that of the base and collector regions.

By fully depleting the area, even if the bipolar transistor is switched off, the doping concentration in the region thus can increase to a level that would otherwise be impossible. This can very advantageously be used, for example, to completely eliminate the Kirk effect at high current densities.

A large number of parameters of the transistor depend substantially on the electric field in the semiconductor area. As the electric field is at least substantially independent of the level and type of the doping, also the cutoff frequency and the breakdown voltage are at least substantially independent of the level and type of the doping.

The substantially ideal behavior of the cutoff frequency and an improved breakdown voltage enable the Johnson limit to be approached.

The bipolar transistor is a vertical transistor, i.e. the charge carriers are injected from the emitter region into the base region after which they drift through the depleted semiconductor area and, in the collector region, to a collector contact. The charge carrier transport in the semiconductor area is vertical owing to the very large strength of the electric field. Therefore it is useful to take the width of the semiconductor area into consideration, which is defined as the distance between the base region and the collector region. If the transistor is switched off, the integral of the electric field across the depletion region is the built-in voltage. The value of the electric field increases as the width of the semiconductor area decreases. The electric field is substantially constant in the semiconductor area if the distance between the base region and the collector region is comparatively small relative to the maximally depletable distance at the given doping of the semiconductor area and the built-in voltage of the base-collector junction. As the doping of the base region and the collector region exceeds the doping in the semiconductor area, the depletion region of the base-collector junction is largely situated in the semiconductor area. Thus, in a very rough approximation, the built-in voltage applied across the base collector junction is the product of the electric field in the semiconductor area and the width of the semiconductor area.

The strength of the electric field is further increased by applying a reverse base-collector voltage.

The comparatively small width of the completely depleted semiconductor area has the important advantage that the cutoff frequency is very high as the presence of the charge carriers in the semiconductor area is limited to a minimum amount of time because, owing to the very strong, substantially constant electric field throughout the area, they move at the saturated drift velocity. In addition, the small width has the advantage that comparatively few charge carriers acquire sufficient kinetic energy in the electric field in the semiconductor area to bring about impact ionization that leads to breakdown.

The base-collector breakdown voltage and the related emitter-collector breakdown voltage can be increased.

By virtue thereof, it becomes possible to increase the product of the cutoff frequency and the collector-emitter breakdown voltage relative to prior-art transistors, and to approach, or even exceed, the Johnson limit.

In general, the doping concentration in the base region is optimized for a certain current setting and a short base transit time. As the doping concentration in the collector region is limited by the solubility product of doping atoms, there is a maximum distance over which the semiconductor area can be depleted of charge carriers. As the collector region is comparatively heavily doped, i.e. typically in excess of 5×10¹⁸ cm⁻³ for Si, the depletion region of the base-collector junction always lies in the semiconductor area, even if the semiconductor area has the same doping type as the base region.

Also in the case of a comparatively heavy doping of the semiconductor area of, for example, 5×10¹⁷ cm⁻³ for Si, and in the absence of a reverse voltage across the collector, i.e. a collector base voltage of 0 V, the semiconductor area is depleted. The maximum distance over which the semiconductor area can be depleted is approximately 170 nm, at the given values for Si. The electric field must be very strong to be independent of the level and type of the doping, typically >10⁵ V/cm. For Si bipolar transistors, the width of the semiconductor area is below 100 nm. After all, this results, at a built-in voltage of approximately 1 V in an electric field of 1 V/100 nm=10⁵ V/cm. For transistors made of different semiconductor materials, such as GaAs or InP, the width of the semiconductor area is comparable due to the comparable value of the built-in voltage and comparable electric fields.

At high current densities, the cutoff frequency is largely determined by the transit time of charge carriers through the semiconductor area. The electric field always is very strong, independent of the doping of the semiconductor area. As a result of this very strong electric field, the charge carriers in the semiconductor area move at the saturated drift velocity. Thus, the transit time is determined only by the width of the semiconductor area, not by the doping level.

An additional advantage of the depleted semiconductor area is that the small signal behavior of the transistor is linear, also at high current densities. For small currents, the collector-base capacitance is constant. At large currents, the charge storage in the collector is dominant and hence limits the velocity of the transistor. As the electric field is very strong in the semiconductor area, the charge carriers always move at the saturated drift velocity, independent of the applied voltage. Thus, the stored charge scales linearly with the current. By virtue of this linear behavior, the transistor can very suitably be operated at high currents and high frequencies.

As the semiconductor area has a comparatively small width, i.e. for Si typically below 100 nm, the distribution of the electric field takes place in a very narrow area. The collector-base junction breaks down as a result of impact ionization. Impact ionization is not a localized effect. The charge carriers need some time and space to warm up in the electric field before they have acquired sufficient energy to cause impact ionization. As the peak in the electric field is narrower than the energy relaxation length of the charge carriers, less impact ionization occurs. The relaxation length for Si is approximately 65 nm. This non-local avalanche effect causes a comparatively high collector-base breakdown voltage. The collector-emitter breakdown voltage is a function of the collector-base voltage and the current amplification of the transistor. Due to the comparatively high collector-base voltage, the collector-emitter breakdown voltage is comparatively high too relative to transistors without a depleted semiconductor area. At a very small width of the semiconductor area of approximately 35 nm for Si, the collector-emitter breakdown voltage converges to a value that is independent of the doping. The collector-emitter breakdown voltage BVceo then depends only on the width of the area, and not on the doping. In this case, the collector-emitter breakdown voltage is never below 1.8 V for Si. Thus, at extremely small widths of the semiconductor area, the collector-emitter breakdown voltage remains comparatively high.

Very advantageously, the width of the semiconductor area is very small, typically below 35 nm for Si. As a result of non-local avalanche effects in the depleted semiconductor area, the collector-emitter breakdown voltage is comparatively high. Both the collector-emitter breakdown voltage BVceo and the cutoff frequency are independent of the doping in the semiconductor area and are only a function of the width of the depleted semiconductor area. The invention enables ultra rapid bipolar transistors having a comparatively very high collector-emitter breakdown voltage to be obtained. The Johnson limit of 200 VGHz in silicon is exceeded at a width of typically 35 nm.

Preferably, the base region of the bipolar transistor is made of a semiconductor material that differs from that used for the collector and the emitter, the bipolar transistor forming a heterojunction bipolar transistor. The bipolar transistor may be a heterostructure comprising, for example, AlGaAs, InAlAs or SiC as the semiconductor material in the emitter and collector regions, and GaAs, InGaAs or Si as the semiconductor material in the base region.

In comparison with a homojunction bipolar transistor, the doping level in the base region may be higher, which can be attributed to the difference in bandgap. This has the favorable effect that the resistance in the base region is smaller than in homojunction bipolar transistors. Besides, the mobility of charge carriers in for example GaAs is much higher than in Si, resulting in a substantially reduced charge storage in the base region. In general, the speed of heterojunction bipolar transistors is much higher than that of homojunction transistors. Charge storage in the collector is generally responsible for the limitation in speed. The invention enables charge storage in the collector to be reduced substantially and the speed of the transistor to be increased.

To enable the bipolar transistor to be readily integrated with other semiconductor devices, such as CMOS or memories, the transistor is advantageously made of Si. The semiconductor material of the emitter and collector regions is silicon, and the semiconductor material of the base region comprises SiGe. Said SiGe is deposited as a layer by means of, for example, CVD, with the percentage of Ge determining the size of the bandgap.

In the silicon-germanium heterojunction bipolar transistor, it is important to the known transistors that the doping of the base region remains within the Si—Ge layer, so as to preclude that a parasitic energy barrier forms on the emitter side as well as the collector side. Such a parasitic energy barrier reduces the advantageous effect of the SiGe layer. In the transistor in accordance with the invention, wherein the semiconductor area is situated between the base region and the collector region, the built-in voltage is sufficient to counteract the disadvantageous effect of the parasitic energy barrier on the collector side. Thus, the bipolar transistor in accordance with the invention is less sensitive to process variations in the base region.

The invention also aims at providing a method of manufacturing the bipolar transistor of the type described in the opening paragraph, which method enables a comparatively thin layer of semiconductor material with an accurately adjustable doping concentration to be reliably obtained between the base and collector regions.

The object of the invention regarding the method is achieved in accordance with the invention in that semiconductor material is epitaxially provided over the collector region so as to form an epitaxial layer, and the epitaxial layer is doped in situ, and, subsequently, the base region is epitaxially provided. The collector region may be a semiconductor substrate, a semiconductor body or a layer or region formed on a substrate.

The layer of semiconductor material typically has a lower doping concentration than the collector, base or emitter regions, so that the semiconductor layer is depleted of charge carriers. As the cutoff frequency and the collector-emitter breakdown voltage depend substantially on the thickness of the semiconductor layer, it is important that diffusion of the doping of the collector region and base region is limited as much as possible during the manufacturing process. To keep the thermal budget as small as possible, advantageously, the collector region, the layer of semiconductor material, the base region and the emitter region are successively epitaxially provided and doped in situ, instead of providing the doping by means of ion implantation and electrically activating said doping in a high-temperature step. The semiconductor material of the bipolar transistor may be crystalline silicon, III-V semiconductors, Si—Ge, Si—C layers or other compounds.

Preferably, the thickness of the layer of semiconductor material is below 100 nm. The doping concentration profiles of the base region and the collector region bounding the in situ-doped semiconductor layer must be steeper as the thickness of the layer of semiconductor material is smaller. Autodoping and outdiffusion of the doping from the base region or collector region into the semiconductor layer can reduce the thickness of the in situ-doped semiconductor layer. A bipolar transistor that can be manufactured comparatively readily comprises a silicon collector region on which an epitaxial layer of Si is deposited and doped in situ with As by means of CVD at temperatures around 700° C. Outdiffusion of doping atoms is reduced substantially by adding a small quantity of C, typically 0.2-0.3 at. %, to Si and Si—Ge layers.

In the case of a SiGe heterojunction bipolar transistor, the base region is situated in a layer of SiGe semiconductor material. After the in situ-doped Si semiconductor layer has been deposited, it is possible to start depositing SiGe in the layer of semiconductor material. Thus, in addition to silicon, the layer of semiconductor material also comprises SiGe.

Transistors made of silicon generally comprise a base region that is p-type doped with B and a collector region that is n-type doped with, for example, As or Sb. During various steps in the process, for example during the provision of isolating material between the bipolar transistors in, for example, a BiCMOS process, it is important to keep the temperature below 900° C. as much as possible so as to preclude diffusion of doping atoms from the base or collector into the in situ-doped semiconductor layer, leading to overdoping of said layer.

An emitter region can be formed by applying a polysilicon layer with doping atoms of a first doping type and, subsequently, diffusing the doping atoms in the base region. Also in this diffusion step, the temperature preferably remains below 900° C. and the duration of the heating process is very short. This can be achieved using, for example, rapid thermal annealing (RTA) or laser annealing.

These and other aspects of the bipolar transistor in accordance with the invention will be apparent from and elucidated with reference to the embodiment(s) described hereinafter.

In the drawings:

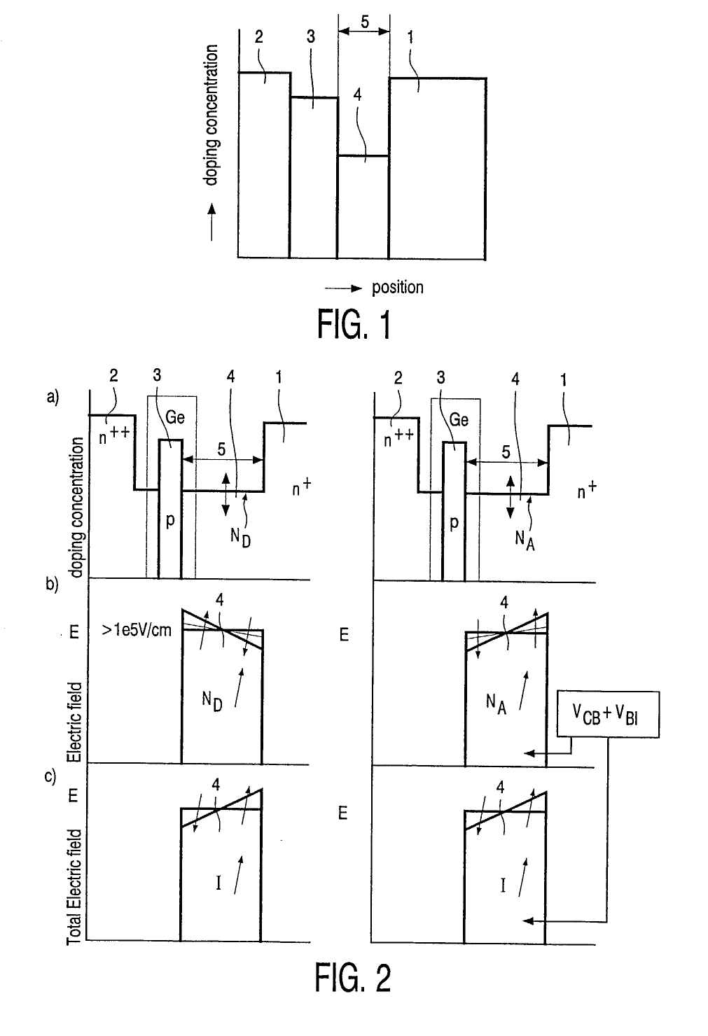

FIG. 1 diagrammatically shows the bipolar transistor in accordance with the invention;

FIG. 2 diagrammatically shows the operation of the bipolar transistor in accordance with the invention, wherein

FIG. 2a shows the doping concentration as a function of the position for an NPN transistor comprising n-type or p-type doping atoms in the semiconductor area;

FIG. 2b shows the electric field in the semiconductor area for n-type or p-type doping atoms and different doping concentrations;

FIG. 2c shows the whole electric field in the semiconductor area at a reverse voltage across the collector-base junction, and different current densities.

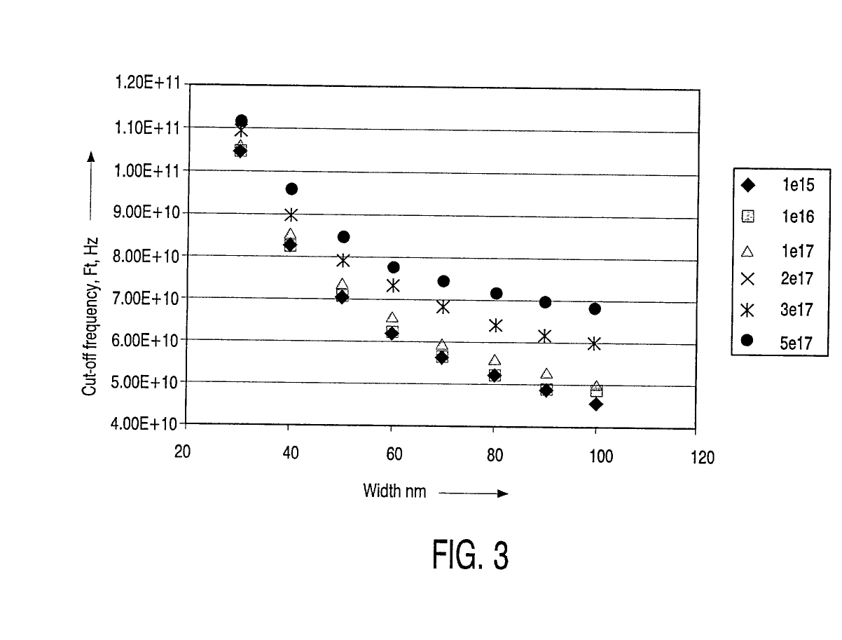

FIG. 3 shows data regarding the cutoff frequency as a function of the width of the semiconductor area for the bipolar transistor in accordance with the first embodiment. The n-type doping concentration in the semiconductor area varies;

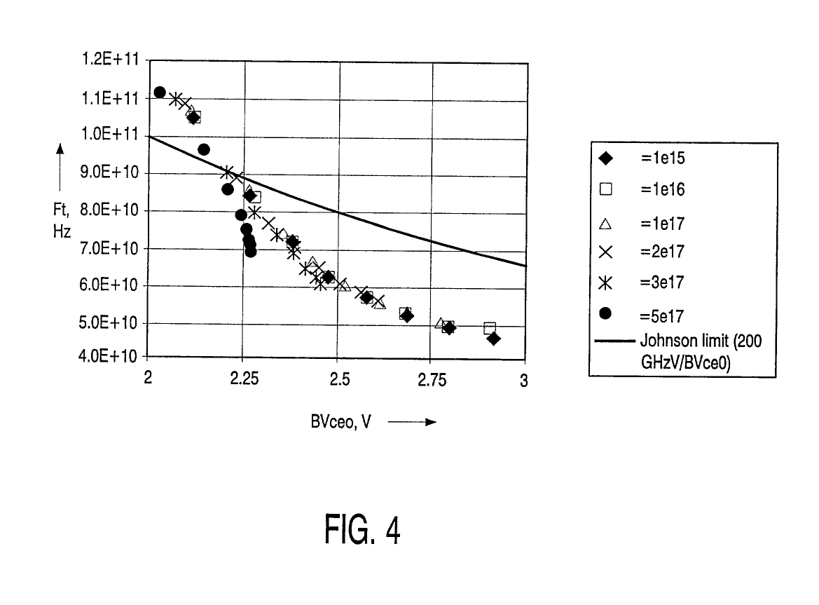

FIG. 4 shows data regarding the cutoff frequency as a function of the collector-emitter breakdown voltage at different n-type doping concentrations for the bipolar transistor in accordance with the first embodiment. The width of the semiconductor area varies from 30-100 nm in steps of 10 nm;

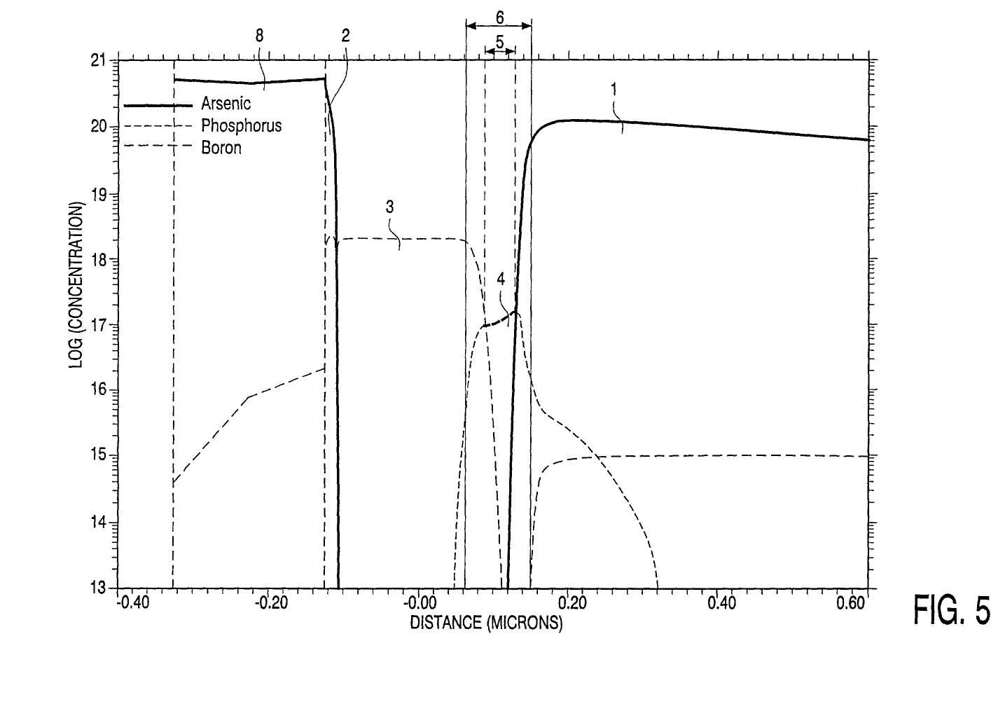

FIG. 5 shows a doping profile of a bipolar transistor wherein the layer of semiconductor material is situated between the base region and the collector region, said bipolar transistor being manufactured by means of the method in accordance with the invention.

It is to be noted that all Figures are diagrammatic and not drawn to scale; for clarity, the relative dimensions of the parts are extended and reduced. In general, reference numerals refer to corresponding or identical parts.

The bipolar transistor shown in FIG. 1 comprises a collector region 1, an emitter region 2 and a base region 3 that is situated between the emitter region 2 and the collector region 1. Said regions are made of a semiconductor material. The base region 3 has a second doping type, opposite to a first doping type of the emitter region and the collector region. A semiconductor area 4 extends between the collector region 1 and the base region 3. The semiconductor area is more lightly doped than the collector region 1, base region 3 and emitter region 2.

The different transistor regions can be made of, for example, crystalline silicon, III-V semiconductors, Si—Ge, Si—C layers or other compounds. It is of essential importance that the semiconductor area 4 is fully depleted. The strength of the intrinsic electric field in the semiconductor area 4 is at least substantially independent of the doping type and the level of the doping in the semiconductor area 4. Depletion of the semiconductor area has the advantage that, in the switched-off state of the transistor, the semiconductor area can be more heavily doped than in a situation where the semiconductor area is not depleted. The higher doping leads to an increase of the maximum current density when the device is in operation.

The bipolar transistor is suitable for operation at high frequencies and, in particular, enables the breakdown voltage to be increased without influencing the cutoff frequency. As a result of non-local avalanche effects, the highest possible product of the cutoff frequency and the collector-emitter breakdown voltage can exceed the Johnson limit.

In the diagrammatic representation of FIG. 2, the bipolar transistor is an NPN heterojunction bipolar transistor with a p-type base and an n-type emitter and collector. The p-type doping of the base region lies entirely in an SiGe layer. The doping in the semiconductor area is generally lower than the doping in the base region or collector region. The n-type doping of the collector region exceeds 5×10¹⁸ cm⁻³. The doping of the base region typically exceeds 5×10¹⁷ cm⁻³.

The semiconductor area may be n-type doped, as indicated on the left-hand side in FIG. 2a, or p-type doped as indicated on the right-hand side. The arrow at the donor and acceptor concentration indicates that the concentration can be varied over a wide range, as long as the semiconductor area is depleted. Also at a comparatively high doping of the semiconductor area of, for example, 5×10¹⁷ cm⁻³, and in the absence of a reverse voltage across the collector, i.e. the collector-base voltage is 0 V, the semiconductor area is depleted. In this case, the maximum distance over which the semiconductor area can be depleted is approximately 170 nm.

The intrinsic electric field shown in FIG. 2b is very strong, typically >10⁵ V/cm, in the fully depleted semiconductor area. The built-in voltage across the collector-base junction is sufficient to generate this very strong intrinsic electric field. An additional electric field resulting from doping atoms in the semiconductor area causes the electric field to be tilted in the direction indicated by the arrows. The very strong electric field resulting from the built-in voltage of the base-collector junction is influenced to a comparatively small extent by the type of doping atoms and the doping level, and is further increased by a reverse voltage applied across the collector-base junction. The integral across the electric field and the width of the semiconductor area corresponds approximately to the sum of the built-in voltage V_{BI} and the reverse voltage V_{CB} applied across the collector-base.

FIG. 2c shows that as a result of the increase in current density I, the maximum in the overall electric field can shift from the border between the base region and the semiconductor area to the border between the semiconductor area and the collector region (see left drawing in FIG. 2c). However, the change of the overall electric field is small due to the applied current.

The influence of the level of the n-type doping in the semiconductor area on the cutoff frequency as a function of the width of the semiconductor area is shown in FIG. 3. Cutoff frequency calculations are performed for a bipolar transistor comprising an n-type collector region with a doping of 2×10²¹ cm⁻³, a thin SiGe layer comprising 20% Ge with a p-type doping having a doping concentration of 1×10¹⁸ cm⁻³, which serves as the base region. The emitter region has a doping concentration of 2×10²¹ cm⁻³. The emitter region is provided with an emitter contact. The calculations are performed at a collector-base voltage of 0 V. The simulated data clearly show the favorable influence that the reduction of the width of the semiconductor area from 100 nm to 30 nm, in steps of 10 nm, has on the cutoff frequency. The increase of the doping concentration from 1×10¹⁵ cm⁻³ to 5×10¹⁷ cm⁻³ leads to an increase of the cutoff frequency due to the smaller charge storage. A reduction of the width of the semiconductor area from 100 nm to 30 nm causes the influence of the doping level on the cutting frequency to become smaller and smaller. The maximum cutoff frequency is 110 GHz at a width of the semiconductor area of 30 nm, and independent of the doping level. The charge carriers move through the depleted semiconductor area at saturated drift velocity. The maximum cutoff frequency is attained at high current densities of typically 5 mA/μm². The current intensity can be much higher than in conventional devices as a result of the fact that the doping concentration in the semiconductor area can be higher. In the simulations shown in FIG. 3, the cutoff frequency increases linearly at a linear decrease of the width 5 of the semiconductor area 4 at a value of approximately 60 nm.

The invention enables the standard limit of the product of the cutoff frequency and the collector-emitter breakdown voltage to be exceeded.

The influence of the level of the n-type doping in the semiconductor area on the cutoff frequency as a function of the collector-emitter breakdown voltage is shown in FIG. 4. The simulated transistor has the same doping concentrations as in the calculations mentioned hereinabove. As expected, the collector-base breakdown voltage decreases if the doping concentration increases from 1×10¹⁵ cm⁻³ to 5×10¹⁷ cm⁻³. The simulated data clearly show the favorable influence of the increase of the doping concentration from 1×10¹⁵ cm⁻³ to 5×10¹⁷ cm⁻³ on the cutoff frequency for widths of the semiconductor area of 100 nm. However, as the width decreases, i.e. to approximately 50 nm, the dependence of the cutoff frequency on the doping concentration is reduced substantially. The solid line shown in FIG. 4 indicates the Johnson limit of 200 VGHz. The Figure clearly shows that if the width of the semiconductor area is reduced from 100 nm to 30 nm in steps of 10 nm, corresponding to the same symbols extending from the bottom right to the top left in FIG. 4, the Johnson limit is exceeded. At a doping concentration of, for example, 3×10¹⁷ cm⁻³, the Johnson limit is exceeded at a width of the semiconductor area below 40 nm. The invention enables an SiGe HBT bipolar transistor having a breakdown voltage of 2 V and a cutoff frequency of 110 GHz to be obtained. However, in the data shown of the transistor in accordance with the first embodiment, the emitter region and the base region are not optimized. By means of the invention and an optimized emitter and base region, it is possible to attain a cutoff frequency of 210 GHz at a breakdown voltage of 1.8 V. Thus, the Johnson limit of 200 VGHz is amply exceeded and is 378 VGHz for this optimized transistor.

In an advantageous method of manufacturing a bipolar transistor, a layer 6 of a semiconductor material is provided over a collector region 1 of Si semiconductor material with an n-type doping of 1×10²⁰ cm⁻³. As atoms. The epitaxial layer 6 is doped in situ. In the embodiment shown in FIG. 5, the epi layer is n-type doped with P atoms in a concentration of 10¹⁷ cm⁻³.

The layer of semiconductor material 6 has a thickness 7 below 100 nm. In the embodiment shown, the thickness of the epi layer after the epitaxial growth is 80 nm and is doped with phosphor atoms in a doping concentration of 10¹⁷ cm⁻³. Subsequently, the isolation is provided in the form of shallow trench isolation, the temperature being kept below 900° C.

Subsequently, the base region 3 is formed by epitaxially providing an Si or SiGe layer and subsequently doping it in situ with B atoms. The Si or SiGe layer is epitaxially grown on the layer 6 of semiconductor material by means of chemical vapor deposition at a temperature of approximately 700° C. In the embodiment shown, the B concentration in the base region is 2×10¹⁸ cm⁻³, and the thickness of the Si base region is 200 nm.

In the case of an SiGe heterojunction bipolar transistor, the base region is situated in a layer of SiGe semiconductor material. The base region comprises, for example, a differentially, epitaxially grown layer packet of 20 nm intrinsic SiGe (18% Ge), 5 nm SiGe (18% Ge) doped with boron in a concentration of 6×10¹⁹ cm⁻³, and 10 nm intrinsic SiGe (18% Ge).

After the deposition of the in situ-doped Si semiconductor layer, it is possible to start depositing SiGe in the layer of semiconductor material. In this case, apart from silicon, the layer of semiconductor material also comprises SiGe.

The emitter region is formed on the base region. The emitter region 2 is formed by providing a typically 200 nm thick polysilicon layer 8 by means of a CVD process at a temperature of typically 600-700° C. N-type doping atoms, such as P or As, are provided in situ during the growth process. In this embodiment, As is implanted in a concentration of 2×10¹⁵ cm⁻³ in the polysilicon layer 8. Subsequently, the doping atoms are diffused in the base region 3. As regards a bipolar transistor in, for example, a BiCMOS process, it is important to keep the temperature below 900° C. as much as possible in order to preclude diffusion of doping atoms from the base or collector into the in situ-doped semiconductor layer 6, which would lead to overdoping of said layer. In the embodiment shown, the duration of the heating process is very short, typically 10 s at 1000° C. in a rapid thermal anneal process.

After these temperature steps, the width 5 of the semiconductor area 4 is reduced from 80 nm to 30-40 nm, as is shown in the concentration profile of the transistor shown in FIG. 5. Although diffusion of doping atoms is limited by a minimum thermal budget, the width 5 of the semiconductor area is reduced in the embodiment shown in FIG. 5. A typical value of the gradient of the electric field on the side of the collector of the semiconductor area is 0.1 V/cm² at a doping level of the collector of 1×10²⁰ cm⁻³.

In an advantageous method, all regions are epitaxially grown and deposited in situ in a CVD process. In this manner, the thermal budget is minimized during the growth of the regions that are doped in situ. The steep doping profiles are advantageous. The comparatively low solubility and electrical activation of the doping atoms at the relevant deposition temperatures are disadvantageous.

To reduce the thermal budget, the isolation between the bipolar transistors and other semiconductor devices, such as CMOS, memory devices such as DRAM, EEPROM, etc. can be provided in a trench by means of a low-temperature deposition technique, such as high density plasma oxide or a spin-on-glass technique.

It is to be noted that the invention is not limited to the examples described hereinabove, and that it can also be used in each bipolar transistor or other heterostructure bipolar transistor. In addition, the invention is not limited to n-type transistors and can also be used for PNP transistors. Besides, the device is not limited to silicon; use can also be made of germanium, germanium silicon, III-V and SiC bipolar devices.

The above-mentioned specific dimensions and materials of the specific embodiments can be varied, as will be clear to any person skilled in the art.

1. A bipolar transistor comprising:
a collector region (1) of a semiconductor material with a first doping type,
an emitter region (2) of a semiconductor material with the first doping type, and
a base region (3) of a semiconductor material with a second doping type, opposite to the first doping type, which base region (3) is situated between the emitter region (2) and the collector region (1), a semiconductor area (4) extending between the collector region (1) and the base region (3), characterized in that the collector region (1) is doped such that the semiconductor area (4) is fully depleted and the size of the intrinsic electric field in the semiconductor area (4) is at least substantially independent of the doping types used and the concentration of the doping in the semiconductor area (4).

2. A bipolar transistor as claimed in claim 1, characterized in that the semiconductor area (4) has a width (5), which is defined as the distance between the base region (3) and the collector region (1), the intrinsic electric field in the semiconductor area being at least substantially constant.

3. A bipolar transistor as claimed in claim 2, characterized in that the width (5) is below 100 nm.

4. A bipolar transistor as claimed in claim 2, characterized in that the cutoff frequency is inversely proportional to the width (5) of the semiconductor area (4).

5. A bipolar transistor as claimed in claim 2, characterized in that the collector-emitter breakdown voltage is a linear function of the width (5) of the semiconductor area (4).

6. A bipolar transistor as claimed in claim 2 or 3, characterized in that the product of the cutoff frequency and the collector-emitter breakdown voltage exceeds the Johnson limit.

7. A bipolar transistor as claimed in any one of the preceding claims 1 through 6, characterized in that the base region (3) is made of a semiconductor material that differs from that used for the collector region (1) and the emitter region (2), the bipolar transistor forming a heterojunction bipolar transistor.

8. A bipolar transistor as claimed in claim 7, characterized in that the semiconductor material comprises Si—Ge in the base region.

9. A bipolar transistor as claimed in claim 8, characterized in that said Si—Ge extends in the semiconductor area (4).

10. A method of manufacturing a bipolar transistor comprising a collector region (1) of a semiconductor material with a first doping type, on which a base region (3) of semiconductor material with a second doping type, opposite to the first doping type, is provided, characterized in that semiconductor material is epitaxially provided over the collector region (1) so as to form an epitaxial layer (6), and the epitaxial layer (6) is doped in situ, and, subsequently, the base region (3) is epitaxially provided.

11. A method as claimed in claim 10, characterized in that the semiconductor material is provided until a thickness (7) of the layer (6) is attained which is below 100 nm.

12. A method as claimed in claim 10, characterized in that the epitaxially provided semiconductor material comprises SiGe.

13. A method as claimed in claim 10, characterized in that an emitter region (2) is formed by applying a polysilicon layer (8) with doping atoms of a first doping type and subsequently diffusing the doping atoms in the base region (3).
